(19) United States
(12) Patent Application Publication
(10) Pub. No.: US 2011/0279119 A1
(43) Pub. Date: Nov. 17, 2011

(54) COMBINABLE MULTIPART SURFACE COIL FOR MAGNETIC RESONANCE TOMOGRAPHY

(76) Inventors: Daniel Driemel, Oederan (DE); Steffen Wolf, Rottenbach (DE)

(21) Appl. No.: 13/104,792

(22) Filed: May 10, 2011

(30) Foreign Application Priority Data
May 11, 2010 (DE) DE102010020153.7

(51) Int. Cl. G01R 33/32

(52) U.S. Cl. 324/318

(57) ABSTRACT

The present embodiments relate to a local coil system for use in a magnetic resonance tomography system. The local coil system includes a local coil lower part and a plurality of mutually different local coil upper parts. Each local coil upper part of the plurality is connectable to the local coil lower part to form a local coil.

This application claims the benefit of DE 10 2010 020 153.7, filed on May 11, 2010.

### BACKGROUND

The present embodiments relate to a magnetic resonance tomography local coil system for use in a magnetic resonance tomography system.

Magnetic resonance devices for examining objects or patients using magnetic resonance tomography (e.g., MR, MRT, MRI) are known, for example, from DE10314215B4.

MR local coils are used for MR imaging of an animal or human.

Local coils are used to examine different body regions. Some of the local coils are, for example, head coils, neck coils or knee coils. Many MR local coils (also referred to as surface coils below) consist of a number of coil parts so that it is easier for a patient to enter the surface coil. There are also surface coils with a varying number of receive channels. Head coils, for example, have 4, 8, 12, 32 or more receive channels.

Specific surface coils may be used for many body regions. Surface coils with few receive channels, high channel surface coils as surface coils, and coils of different sizes are also known.

### SUMMARY AND DESCRIPTION

The present embodiments may obviate one or more of the drawbacks or limitations in the related art. For example, local coil systems may be optimized.

A local coil system of the present embodiments includes a local coil lower part and a plurality of mutually different local coil upper parts, each local coil upper part of the plurality of local coil upper parts being connectable (e.g., fitted together) to the local coil lower part to form a local coil.

### BRIEF DESCRIPTION OF THE DRAWINGS

FIG. 1 shows one embodiment of a local coil system including a local coil upper part and a local coil lower part that are connected by fitting together;

FIG. 2 shows one embodiment of a local coil system including a head/neck local coil upper part and a local coil lower part in an unfitted state;

FIG. 3 shows a bottom view of one embodiment of the head/neck local coil upper part of FIG. 2;

FIG. 4 shows one embodiment of a local coil system including a neck local coil upper part and a local coil lower part that are connected by fitting together;

FIG. 5 shows one embodiment of the neck local coil upper part from FIG. 4;

FIG. 6 shows one embodiment of a head coil local coil system including a local coil upper part for a lateral head region and a local coil lower part that are connected by fitting together;

FIG. 7 shows one embodiment of a head coil local coil system including a brain local coil upper part and a local coil lower part that are connected by fitting together;

FIG. 8 shows one embodiment of a head coil local coil system including a local coil upper part for a central facial region and a local coil lower part that are connected by fitting together; and

FIG. 9 shows a schematic view of an MRT system.

### DETAILED DESCRIPTION OF THE DRAWINGS

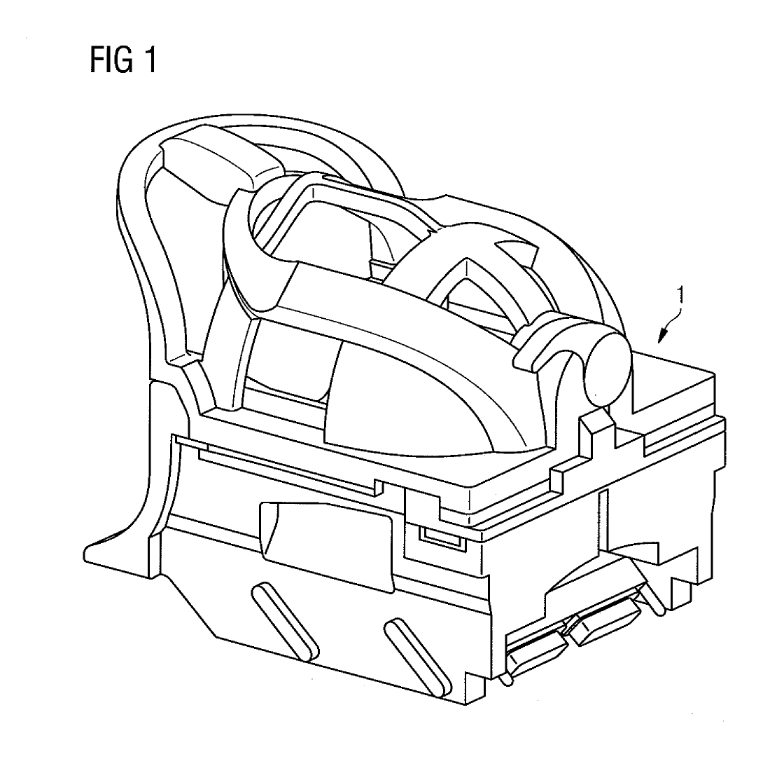

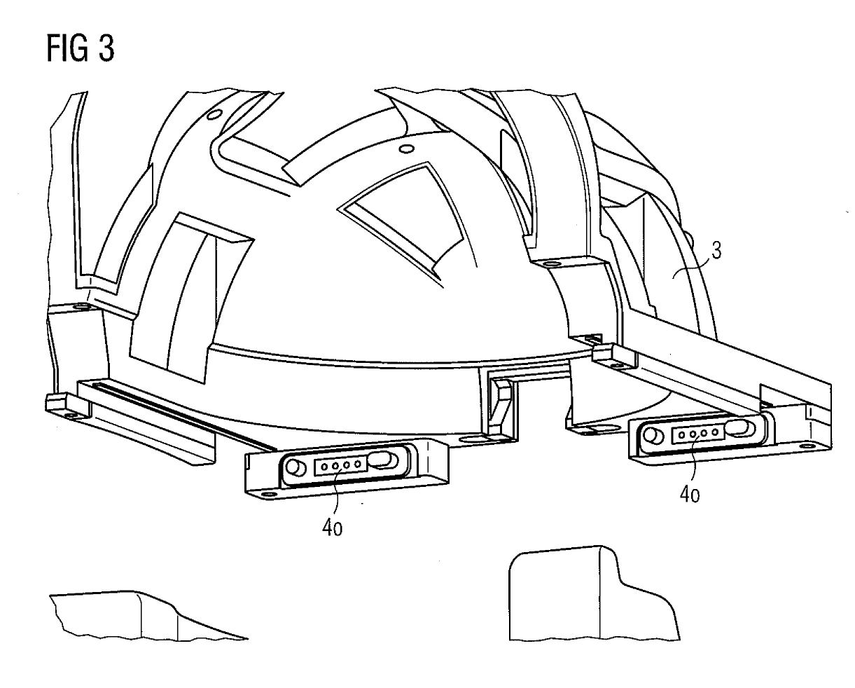

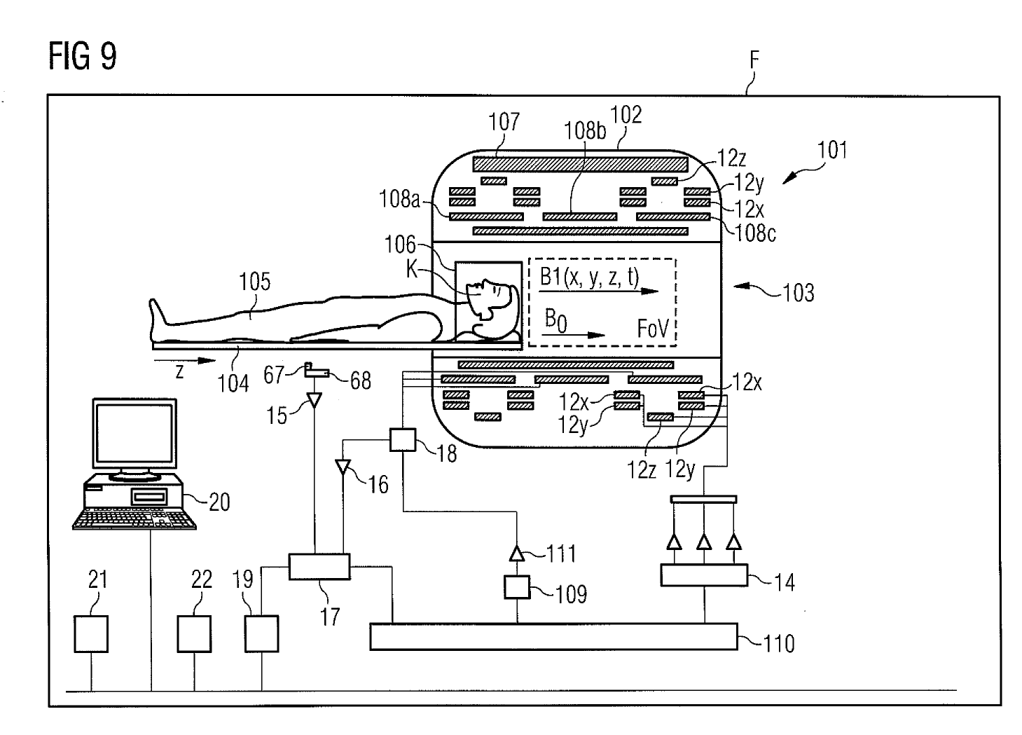

FIG. 9 shows a magnetic resonance imaging device MRT 101 having a whole body coil 102 with, for example, a tubular chamber 103, into which a patient couch 104 (e.g., a patient bed) holding a body of a patient 105 (e.g., with a local coil arrangement 6), for example, may be moved in the direction of the arrow z, to generate recordings of the patient 105. In the embodiment shown in FIG. 9, the local coil arrangement 106 (shown in detail in FIGS. 1-8) is positioned on the patient 105. The local coil arrangement 106 may be used when the patient 105 is moved in the direction z into the field of view (FoV) to take recordings of a local region (e.g., the head K). Signals from the local coil arrangement 106 may be evaluated by an evaluation unit (e.g., elements 67, 15, 17) of the MRT 101 that may be connected by way of a coaxial cable or wirelessly to the local coil arrangement 106 (e.g., for being converted to images and stored or displayed).

In order to use the magnetic resonance device MRT 101 to examine the body 105 (e.g., an examination object or patient) using magnetic resonance imaging, different magnetic fields with mutually matched temporal and spatial characteristics are radiated onto the body 5. A powerful magnet (e.g., a cryomagnet 107) in a measurement chamber with the tunnel-type opening 103, for example, generates a static powerful main magnetic field B₀, of, for example, 0.2 Tesla to 3 Tesla or even more. The body 105 to be examined is supported on the patient couch 104 and moved into a roughly homogeneous region of the main magnetic field B₀ in the field of view FoV. Excitation of the nuclear spin of atomic nuclei of the body 105 takes place by way of magnetic high-frequency excitation pulses that are radiated in by way of a high-frequency antenna shown in FIG. 9 in a simplified fashion as a body coil 108 and/or a local coil arrangement (e.g., high frequency antennas). High-frequency excitation pulses are generated, for example, by a pulse generation unit 109 that is controlled by a pulse sequence control unit 110. After amplification by a high-frequency amplifier 111, the high-frequency excitation pulses are sent to the high-frequency antenna 108 a, b, c. The high-frequency system shown in FIG. 9 is only represented schematically. In other embodiments, more than one pulse generation unit 109, more than one high-frequency amplifier 111 and a number of high-frequency antennas 108 a, b, c are used in the magnetic resonance device 101.

The magnetic resonance device 101 also has gradient coils 12x, 12y, 12z, used to radiate in magnetic gradient fields for selective layer excitation and spatial coding of the measurement signal during a measurement. The gradient coils 12x, 12y, 12z are controlled by a gradient coil control unit 14 that, like the pulse generation unit 9, is connected to the pulse sequence control unit 110.

The signals emitted by the excited nuclear spins are received by the body coil 108a, 108b, 108c and/or at least one local coil arrangement 106, amplified by assigned high-frequency amplifiers 16 and further processed and digitized by a receive unit 17. The recorded measurement data is digitized and stored as complex numerical values in a k-space matrix. An associated MR image may be reconstructed from the k-space matrix populated with values using a multidimensional Fourier transformation.

In the case of a coil that may be operated in both transmit and receive mode (e.g., the body coil 108a, b, c, or a local coil) correct signal forwarding is regulated by an upstream branching filter 18.

An imaging processing unit 19 uses the measurement data to produce an image that is displayed to a user by way of an operating console 20 and/or stored in a storage unit 21. A central computer unit 22 controls the individual system components.

In MR tomography, images with a high signal to noise ratio (SNR) may be recorded using local coil arrangements (e.g., local coils). Local coil arrangements are antenna systems that are positioned in direct proximity to (anterior), below (posterior) or in the body. During an MR measurement, excited nuclei induce a voltage in the individual antennas of the local coil, the induced voltage being amplified using a low-noise preamplifier (e.g., LNA, preamp) and forwarded to the electronic receive system. To improve the signal to noise ratio (e.g., even with high-resolution images), high-field systems (e.g., 1.5 T or 3 T and more) are used. Since more individual antennas may be connected to an MR receive system than there are receivers present, a switching matrix (e.g., RCCS) is incorporated between the receive antennas and the receiver. The switching matrix routes the instantaneously active receive channels (e.g., receive channels in the FoV of the magnet at the time) to the receivers present.

This allows more coils to be connected than there are receivers present, since with whole body coverage, the coils located in the FoV or in the homogeneity volume of the magnet are read out.

The local coil system 106 may include, for example, one or a plurality of antenna elements (e.g., coil elements; an array coil). The local coil system 106 includes, for example, coil elements, a preamplifier, further electronic systems, a housing, bearing surfaces, and a wireless connection or a cable with plug to connect the local coil system to the MRT system. A system-side receiver 68 filters and digitizes signals received from the local coil 106, for example, wirelessly or by cable and transmits the data to a digital signal processor. The digital signal processor may derive an image or a spectrum from the data obtained by measurement and makes the image or the spectrum available to a user, for example for, subsequent diagnosis by the user or for storage.

An exemplary embodiment is described below in the form of a local coil lower part 2 of a local coil system as illustrated in FIGS. 1, 2 and 4. The local coil lower part 2 is combinable with mutually different local coil upper parts 3, 6, 7, 8, 9 (e.g., to form the local coil system 106), as illustrated in FIGS. 1-8, by fitting the local coil lower part 2 and the mutually different local coil upper parts 3, 6, 7, 8, 9 together and/or other (mechanical) connection (e.g., screwing, pinning and/or lever engagement connections). The local coil system 106 is also possible for MR surface coils other than those illustrated (e.g., as a knee coil, ankle coil or wrist coil) by using a matching local coil lower part and matching local coil upper parts.

In FIG. 1, the local coil lower part 2 and one of the local coil upper parts 3 of the local coil system 106 are fitted together to form the local coil 1. The local coil lower part 2 and the one local coil upper part 3 may be secured to one another in a fixed manner, for example, using an engagement connection (as illustrated in FIG. 1), a locking system, or in other known manners. When the examination object is lying on the patient couch 104, the local coil lower part 2 may be positioned below the examination object 105, and the local coil upper part may be positioned above the examination object 105.

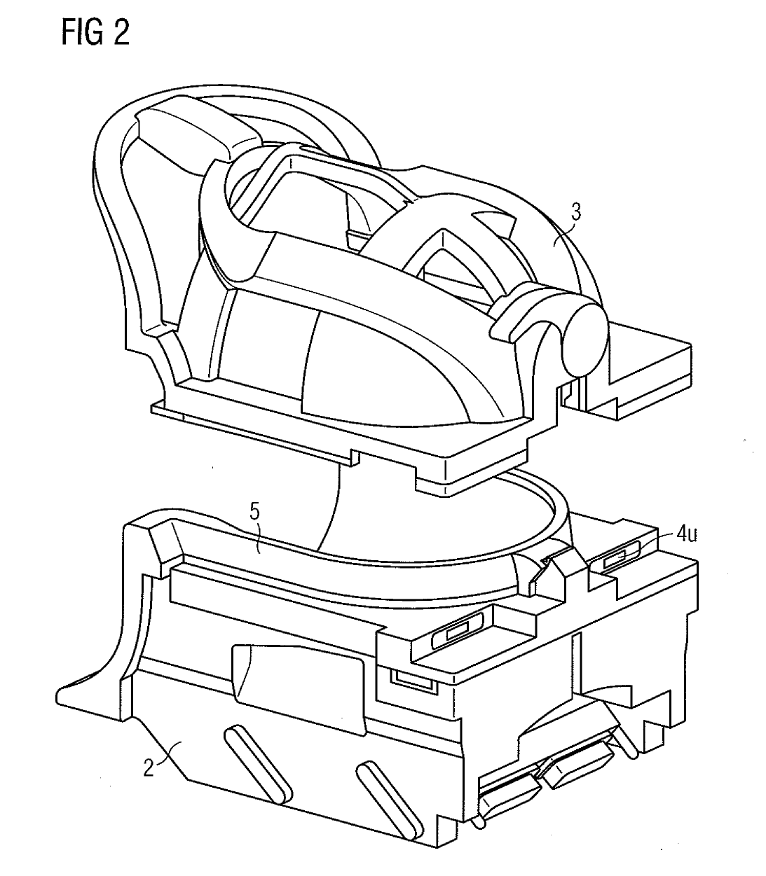

FIG. 2 shows one embodiment of a local coil lower part 2 and a local coil upper part 3 of a local coil system in a state where the local coil lower part 2 and the local coil upper part 3 are not fitted together (to form a local coil).

The local coil lower part 2 may be used, for example, with a different local coil upper part 6, as illustrated in FIGS. 1 and 2, as a head/neck local coil 1, to record the head and neck of a patient or one of the head or neck as an image.

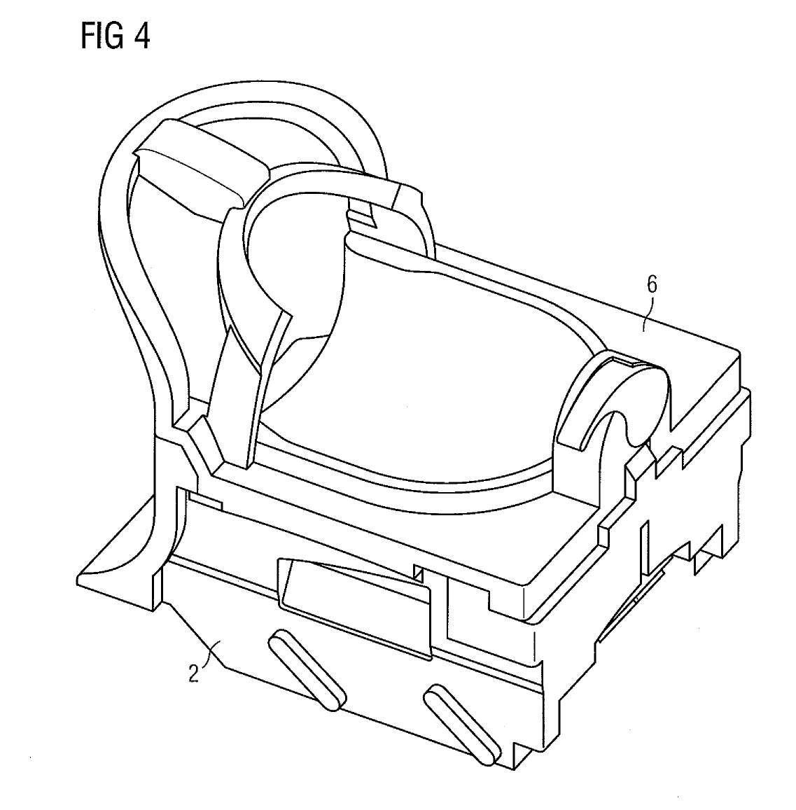

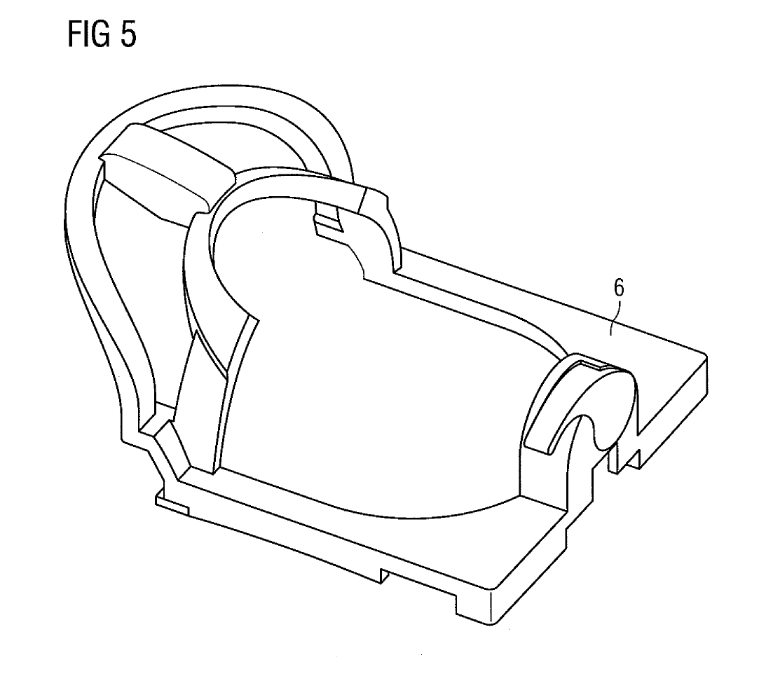

The local coil lower part 2 may also be used, for example, with a different local coil upper part 6, as illustrated in FIGS. 4 and 5, as a neck local coil 1 that covers the neck region of an examination object (e.g., a patient or dummy) and leaves the facial region of the examination object uncovered.

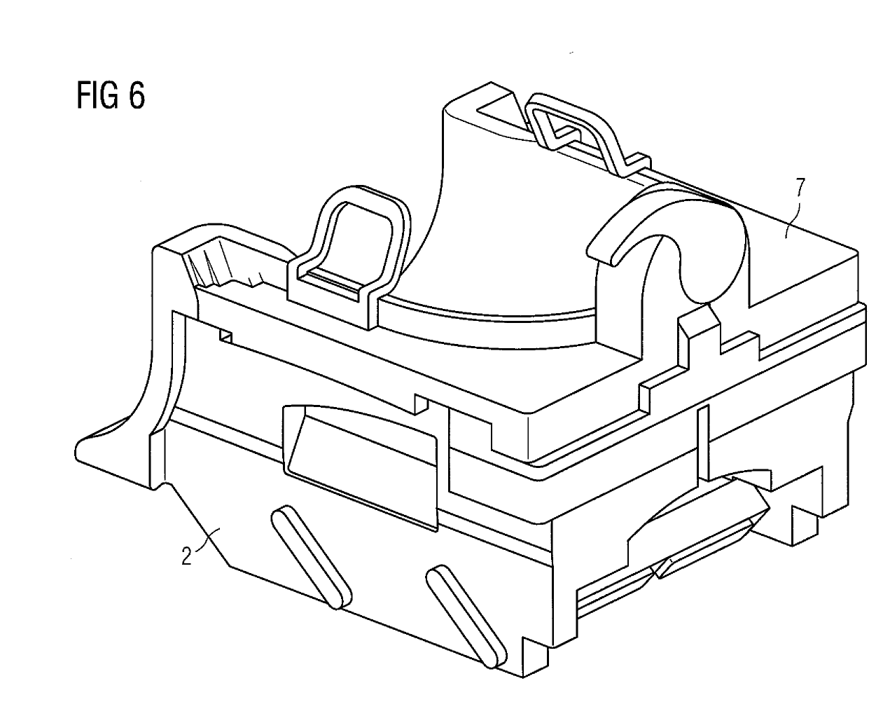

The local coil lower part 2 may also be used, for example, with a local coil upper part 7, as illustrated in FIG. 6, that is different from the local coil upper part 6 in FIG. 5. The local coil lower part 2 and the local coil upper part 7 may be used as a head local coil 1 for a lateral head region (e.g., jaw or sinuses) that covers a lateral head region of the examination object (e.g., of a patient 105 or dummy) and leaves the remainder of the facial region of the examination object 105 uncovered.

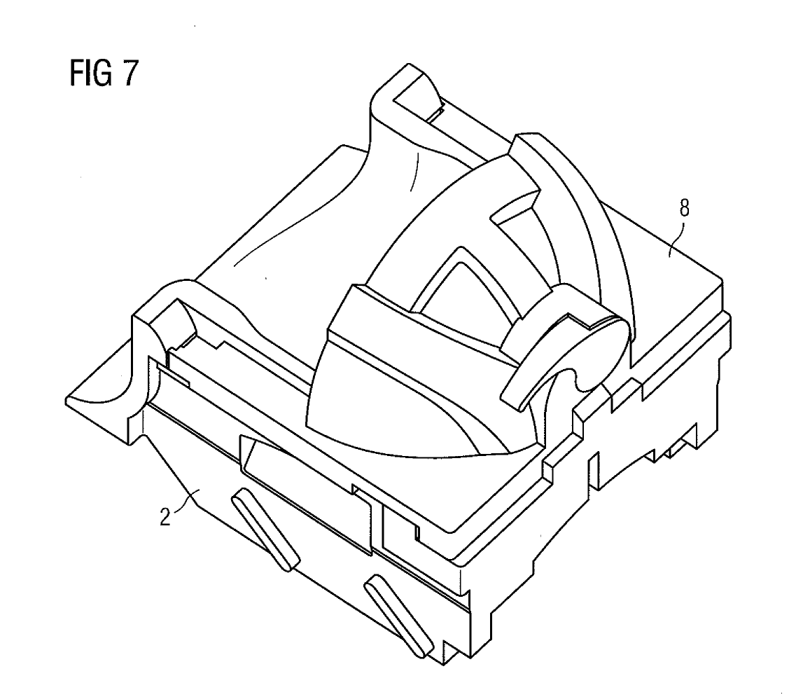

The local coil lower part 2 may, for example, also be used with a different local coil upper part 8, as illustrated in FIG. 7, as a head local coil 1 for an upper head region (e.g., the region above the brain) that covers an upper head region of the examination object and leaves the facial region of the examination object uncovered.

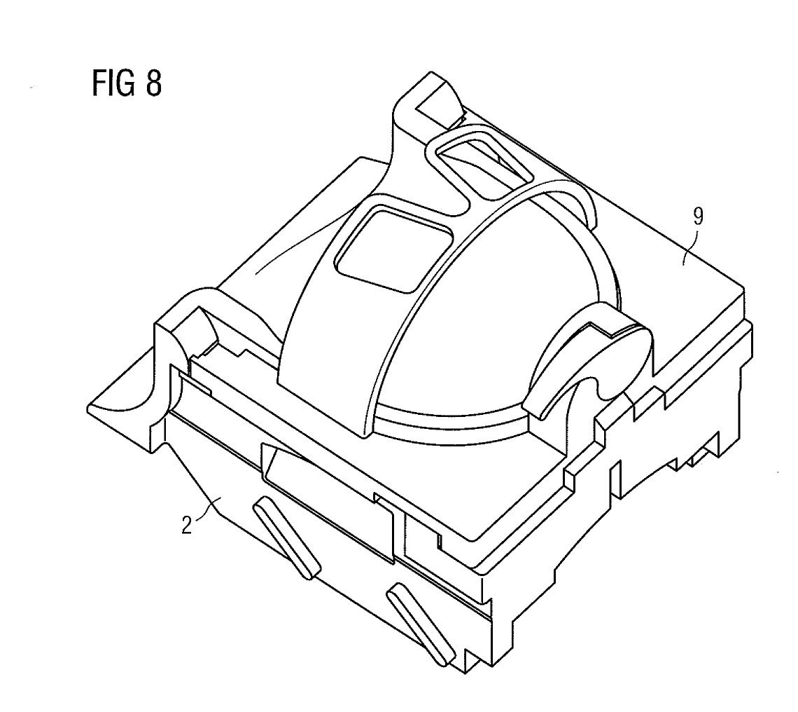

The local coil lower part 2 may, for example, also be used with a different local coil upper part 9, as illustrated in FIG. 8, as a head local coil 1 for a front head region (e.g., the eye region) that covers a front head region of the examination object (e.g., with a spectacle-shaped frame over the eye region) and leaves the remainder of the facial region of the examination object uncovered.

Local coil upper parts 3, 6, 7, 8, 9 may be contacted electrically at the local coil lower part 2 (e.g., for coupling coils in the head part to an MRT by way of a connection between the lower part and the MRT), for example, by way of a plug connection with plugs/sockets 4ₒ in the local coil upper part 3, 6, 7, 8, 9, and matching plugs/sockets 4ᵤ in the local coil lower part 2. Alternatively or additionally, the local coil upper parts 3, 6, 7, 8, 9 and the local coil lower part 2 are connected wirelessly or by way of an external line at another point on the patient couch to the MRT system 1. The local coil lower part 2 may be the mechanical and electrical base for the local coil upper parts 3, 6, 7, 8, 9 or just the mechanical base for the local coil upper parts 3, 6, 7, 8, 9.

If the local coil lower part 2 and one of the local coil upper parts 3, 6, 7, 8, 9 are plugged directly into one another, the combination with high-channel upper parts is limited to the number of terminal contacts provided by the local coil lower part 2. The number of terminal contacts may be correspondingly high for future designs.

The local coil lower part 2 may also be fitted with a collar 5. The respective local coil upper part 3, 6, 7, 8, 9 overlaps with the collar 5. In the interior of the coil 1, individual coil elements (e.g., coils, coil segments) of the local coil lower part 2 and coil elements of the local coil upper part 3, 6, 7, 8, 9 overlap at this point, thereby allowing the geometric decoupling of the coil elements. Element decoupling may prevent direct mutual influencing and signal coupling between adjacent elements.

The (head/neck coil) lower part 2 may be combined with a plurality of local coil upper parts 3, 6, 7, 8, 9. In one embodiment, the head/neck lower part 2 may be combined with a complete head and neck coil upper part 3 (e.g., with dimensions that, as far as available space is concerned, is suitable for 95% of patients). Patients differ in size considerably in the front neck region. Cervical spine imaging is an area of magnetic resonance tomography, where a smaller neck coil upper part 6 may be differentiated and configured for slim patients. A larger neck coil upper part 6 may also be available, offering more space for problem patients with torticollis or Bechterew problems. One advantage of a separate neck coil upper part 6 is that it is less stressful for patients suffering from claustrophobia, in that during a cervical spine examination only the neck upper part 6 may be used on the patient so that the field of vision of the patient is not blocked, in contrast to the full head/neck coil upper part 3.

Other local coil upper parts may be used, for example: for mandibular joint recordings, a local coil upper part 7 according to FIG. 6; a brain upper part 8 according to FIG. 7; an eye coil upper part 9 according to FIG. 8; and an local coil upper part for carotid recordings.

A knee coil lower part may be combined, for example, with a knee coil upper part and an upper part suitable for ankle examinations.

The local coil upper parts 3, 6, 7, 8, 9 may be made available in different sizes and with different channel numbers. A customer may supplement an existing coil lower part with specific further upper parts. The head/neck coil illustrated may be suitable for approximately 95% of patients with a head/neck upper part and may be fitted with a smaller neck upper part.

The local coil lower part 2 as a base for the plurality of local coil upper parts 3, 6, 7, 8, 9 may have the following advantages:
the size of the local coil upper parts may be varied in order to optimize the space available for different patient proportions and to produce the best image quality;
specific applications such as mandibular joint and carotid imaging may utilize the head coil lower part as a patient support and electrical interface and do not use another base or an electricity supply line;
high-channel coil upper parts for head, neck or a brain region may be combinable for research customers, for example;
patients suffering from claustrophobia are only subjected to the upper parts used for the examination; for example, during cervical spine examinations, just one appropriate neck upper part is used without a head upper part 6 so the field of vision of the patient is not blocked;
possible cost savings;
handling benefits for the customer due to the multiple use of one local coil lower part that may remain on the patient couch;
a reduction in the number of local coils the customer uses and therefore, reduced costs and space used; and
a defined overlap surface between the local coil lower part and the local coil upper parts (for the local coil lower part) allows a customer to be supplied with an additional separate local coil upper part for an existing base; the local coil lower parts and local coil upper parts may not be matched to one another during production.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A local coil system for use in a magnetic resonance tomography system, the local coil system comprising:
a local coil lower part; and
a plurality of different local coil upper parts, each local coil upper part of the plurality being connectable to the local coil lower part to form a local coil.

2. The local coil system as claimed in claim 1, wherein the local coil lower part is configured to be positioned below an examination object, and
wherein one local coil upper part of the plurality is configured to be positioned above the examination object.

3. The local coil system as claimed in claim 1, wherein one local coil upper part of the plurality and the local coil lower part in a fitted together state form a head coil.

4. The local coil system as claimed in claim 1, wherein one local coil upper part of the plurality and the local coil lower part in a fitted together state form a neck coil.

5. The local coil system as claimed in claim 4, wherein the one local coil upper part is larger than another local coil upper part of the plurality, the other local coil upper part and the local coil lower part in the fitted together state forming another neck coil.

6. The local coil system as claimed in claim 1, wherein one local coil upper part of the plurality and the local coil lower part in a fitted together state form a head/neck coil.

7. The local coil system as claimed in claim 1, wherein one local coil upper part of the plurality and the local coil lower part in a fitted together state form a knee coil.

8. The local coil system as claimed in claim 1, wherein one local coil upper part of the plurality and the local coil lower part in a fitted together state form an ankle coil.

9. The local coil system as claimed in claim 1, wherein one local coil upper part of the plurality includes contacts, the one local coil upper part being electrically contacted with the local coil lower part via the contacts.

10. The local coil system as claimed in claim 1, wherein one local coil upper part of the plurality includes contacts, the one local coil upper part being electrically connectable to contacts on a magnetic resonance tomography system via the contacts and a line.

11. The local coil system as claimed in claim 1, wherein the local coil lower part includes an outer collar, with which one local coil upper part of the plurality overlaps when the one local coil upper part is positioned on the local coil lower part.

12. The local coil system as claimed in claim 1, wherein in a region of an outer collar of the local coil lower part, with which one local coil upper part of the plurality overlaps in a state in which the one local coil upper part is positioned on the local coil lower part, receive coils of the local coil lower part and receive coils of the one local coil upper part overlap.

13. The local coil system as claimed in claim 1, wherein the local coil lower part and one local coil upper part of the plurality are connectable to one another by positioning the local coil lower part and the one local coil upper part on top of one another.

14. The local coil system as claimed in claim 1, wherein the local coil system is a magnetic resonance tomography local coil system.

15. The local coil system as claimed in claim 3, wherein the head coil is a head coil that covers at least a lateral region of a head, an eye region of the head, or a brain region of the head.

16. The local coil system as claimed in claim 4, wherein the neck coil is a neck coil that only covers a neck in a region of a head and neck of an examination object.

17. The local coil system as claimed in claim 6, wherein the head/neck coil is a head/neck coil that covers a head and neck of an examination object in a region of the neck and head.

18. The local coil system as claimed in claim 9, wherein the one local coil upper part is electrically contacted with the local coil lower part by plugging the contacts into contacts on the local coil lower part.

19. The local coil system as claimed in claim 2, wherein the one local coil upper part and the local coil lower part in a fitted together state form a head coil.

20. The local coil system as claimed in claim 2, wherein the one local coil upper part and the local coil lower part in a fitted together state form a neck coil.
